(19) United States
(12) Patent Application Publication
(10) Pub. No.: US 2026/0214984 A1
(43) Pub. Date: Jul. 23, 2026

(54) STANDARD CELL INCLUDING INTERCONNECTION STRUCTURE

(71) Applicant: Samsung Electronics Co., Ltd., Suwon-si (KR)

(72) Inventors: Jeonggu Sim, Suwon-si (KR); Junghan Lee, Suwon-si (KR); Jaehyoung Lim, Suwon-si (KR); Byungsung Kim, Suwon-si (KR); Kwanyoung Chun, Suwon-si (KR)

(21) Appl. No.: 19/270,677

(22) Filed: Jul. 16, 2025

(30) Foreign Application Priority Data
Jan. 21, 2025 (KR) 10-2025-0008855

(51) Int. Cl. H10D 84/90; H10D 89/10

(52) U.S. Cl. CPC H10D 84/981; H10D 84/953; H10D 89/10

(57) ABSTRACT

The disclosure provides a standard cell and a manufacturing method thereof. The standard cell includes at least one front side interconnection layer and at least one back side interconnection layer. Each layer can be flexibly configured to act as either a power rail or a signal rail.

### CROSS-REFERENCE TO RELATED APPLICATION

This application is based on and claims priority under 35 U.S.C. § 119 to Korean Patent Application No. 10-2025-0008855, filed on Jan. 21, 2025, in the Korean Intellectual Property Office, the disclosure of which is incorporated by reference herein in its entirety.

### TECHNICAL FIELD

The disclosure relates to a standard cell. More specifically, the disclosure relates to a standard cell including a front side interconnection layer and a back side interconnection layer.

### BACKGROUND

As the miniaturization of integrated circuits (ICs) has progressed, a back side power delivery network (BSPDN) is being applied. The BSPDN, as the term implies, is a technology that applies a power delivery network (PDN) to a back side of ICs. Here, networks refer to sets of interconnections, and interconnections may generally refer to metal interconnections. Additionally, the networks may be classified into a signal network and a power delivery network depending on their purpose. The signal network may refer to a set of interconnections used to transmit and receive signals between transistors within ICs, or with external elements. On the other hand, the power delivery network may refer to a set of interconnections that supply power to operate a transistor. The power has been transmitted through a front side of ICs in the related art.

### SUMMARY

The disclosure provides a standard cell including an integrated circuit with an improved integration level.

In addition, the objective to be achieved by the disclosure is not limited to the objective mentioned herein, and other objectives may be clearly understood by those skilled in the art from the description below.

According to an aspect of the disclosure, the disclosure provides a standard cell including a plurality of back side interconnection layers extending in a first horizontal direction, a lower via disposed on the plurality of back side interconnection layers, a first transistor disposed at a higher vertical level than the lower via, wherein the first transistor includes a gate line extending in a second horizontal direction perpendicular to the first horizontal direction, source/drain regions arranged on both sides of the gate line in the first horizontal direction, and a channel layer between the source/drain regions and surrounded by the gate line, a lower source/drain contact between the source/drain regions and the lower via, an upper source/drain contact disposed on the source/drain regions, a plurality of front side interconnection layers extending in the first horizontal direction, and an upper via between the upper source/drain contact and the plurality of front side interconnection layers, wherein the plurality of back side interconnection layers include at least one first back side interconnection layer, and at least one second back side interconnection layer spaced apart from the first back side interconnection layer in the first horizontal direction, and the plurality of front side interconnection layers include at least one first front side interconnection layer, and at least one second front side interconnection layer spaced apart from the first back side interconnection layer in the first horizontal direction.

According to another aspect of the disclosure, the disclosure provides a standard cell including a back side interconnection layer including at least one back side power rail and at least one back side signal rail that extend in a first horizontal direction, respectively, a lower via disposed on the back side interconnection layers, a channel layer disposed at a higher vertical level than the lower via, a gate line that surrounds the channel layer and extends in a second horizontal direction intersecting the first horizontal direction, source/drain regions arranged on both sides of the channel layer in the first horizontal direction, a lower source/drain contact between the source/drain regions and the lower via, an upper source/drain contact disposed on the source/drain regions, a front side interconnection layer including at least one front side power rail and at least one front side signal rail each extending in the first horizontal direction at a higher vertical level than the source/drain regions, and an upper via between the front side interconnection layer and the upper source/drain contact.

According to another aspect of the disclosure, the disclosure provides a standard cell including a plurality of back side interconnection layers spaced apart from each other in a first horizontal direction and a second horizontal direction intersecting the first horizontal direction at a first level, a plurality of gate lines spaced apart from each other in the first horizontal direction and each extending in the second horizontal direction at a second level higher than the first level, a channel layer surrounded by the plurality of gate lines, source/drain regions disposed on both sides of the channel layer, and a plurality of front side interconnection layers spaced apart from each other in the first horizontal direction and the second horizontal direction at a third level higher than the second level, wherein the plurality of back side interconnection layers and the plurality of front side interconnection layers include at least one signal rail and at least one power rail.

### BRIEF DESCRIPTION OF THE DRAWINGS

Implementations will be more clearly understood from the following detailed description taken in conjunction with the accompanying drawings in which:

FIG. 1 is a layout diagram of a standard cell according to some implementations;

FIG. 2A is a plan view selectively illustrating a structure arranged on a front side of a substrate in the layout diagram of FIG. 1;

FIG. 2B is a plan view selectively illustrating a structure arranged on a back side of the substrate in the layout diagram of FIG. 1;

FIG. 3A is a layout diagram of a standard cell according to some implementations;

FIG. 3B is a cross-sectional view taken along line A-A′ of FIG. 3A;

FIG. 4A is a layout diagram of a standard cell according to some implementations;

FIG. 4B is a cross-sectional view taken along line B-B′ of FIG. 4A;

FIG. 5 is a schematic diagram of a portion of a layout diagram to explain the connection between a p-channel metal oxide semiconductor (PMOS) region and an n-channel metal oxide semiconductor (NMOS) region in a standard cell according to some implementations;

FIG. 6A is a cross-sectional view taken along line C-C′ of FIG. 5; and

FIG. 6B is a cross-sectional view taken along line D-D′ of FIG. 5.

### DETAILED DESCRIPTION

Hereinafter, implementations of the disclosure will be described in detail with reference to the attached drawings. The same reference numerals will be used throughout the drawings to refer to the same or like parts, and duplicate descriptions thereof are omitted.

The implementations may be modified in various ways and have many different implementations, and specific implementations are illustrated in the drawings and described in detail in the detailed description of the implementations. However, this is not intended to limit the scope of the disclosure to the specific implementations, and should be understood to include various modifications, variations, equivalents, and alternatives within the sprit or scope of the disclosure. In describing the implementations, a detailed description of related known technologies is omitted when it is not specifically and explicitly necessary.

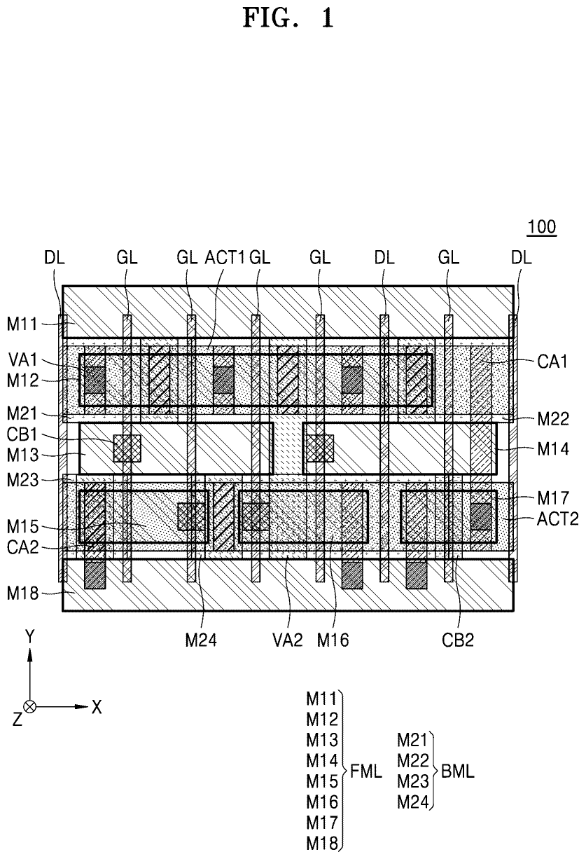

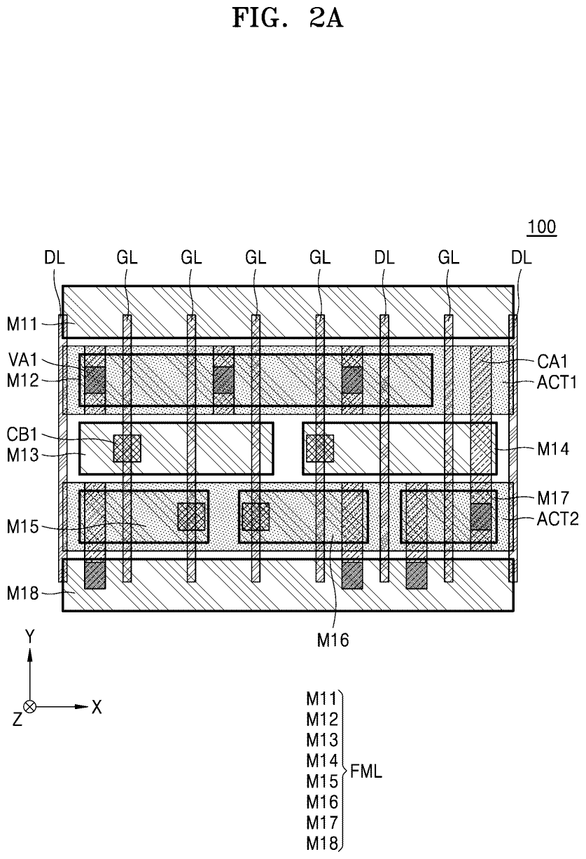

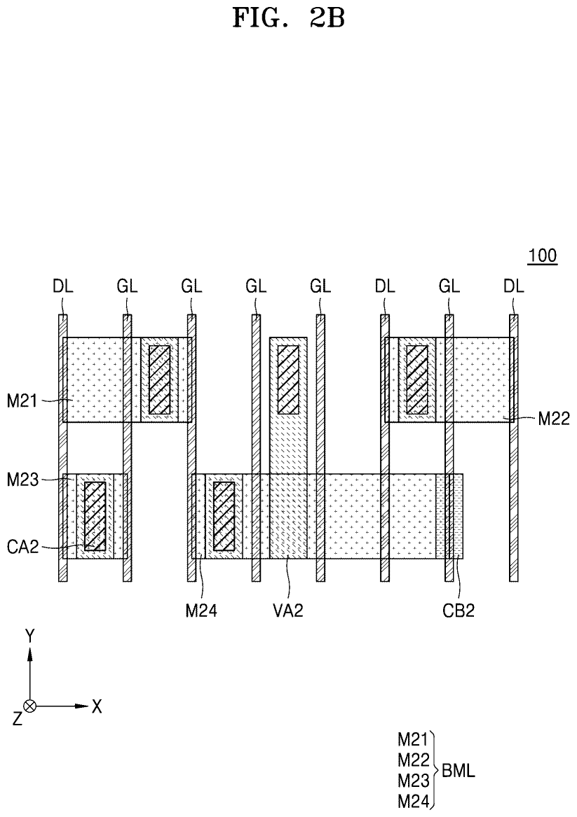

FIG. 1 is a layout diagram of a standard cell 100 according to some implementations. FIG. 2A is a plan view selectively illustrating a structure arranged on a front side of the substrate in the layout diagram of FIG. 1, and FIG. 2B is a plan view selectively illustrating the structure arranged on a back side of the substrate.

Referring to FIGS. 1, 2A, and 2B, implementations of the standard cell may include a back side interconnection layer BML, a front side interconnection layer FML, a lower via VA2, a lower source/drain contact (a lower source contact or a lower drain contact) CA2, a lower gate contact CB2, a first active region ACT1, a second active region ACT2, a gate line GL, a dummy gate line DL, an upper source/drain contact (an upper source contact or an upper drain contact) CA1, an upper via VA1, and an upper gate contact CB1. Here, a back side may refer to a lower side in a vertical direction (a Z direction), and a front side may refer to an upper side in the vertical direction (the Z direction). A term “vertical level” as used herein may refer to the distance from the front side of the substrate in the vertical direction (the +Z direction or the −Z direction). The specific vertical positional relationship of components illustrated in the layout diagram of the standard cell 100 will be described below.

The back side interconnection layer BML and the front side interconnection layer FML may include at least one material selected from a group including Co, Ni, W, Ti, Ta, Cu, Al, TiN, TaN, and combinations thereof. The front side interconnection layer FML may be positioned at a higher vertical level than the back side interconnection layer BML. For convenience of illustration, the back side interconnection layer BML and the front side interconnection layer FML are illustrated as being formed as a single layer in each tier. However, in some implementations, an interconnection layer arranged on the substrate may be configured as a multilayer structure.

In some implementations, the front side interconnection layer FML may include a first front side interconnection layer M11, a second front side interconnection layer M12, a third front side interconnection layer M13, a fourth front side interconnection layer M14, a fifth front side interconnection layer M15, a sixth front side interconnection layer M16, a seventh front side interconnection layer M17, and an eighth front side interconnection layer M18. The first front side interconnection layer M11 and the eighth front side interconnection layer M18 may extend in a first horizontal direction (an X direction) and be spaced apart from each other in a second horizontal direction (a Y direction). The second to seventh front side interconnection layers M12, M13, M14, M15, M16, and M17 may each have a length of the first horizontal direction (the X direction) shorter than that of each of the first and eighth front side interconnection layers M11 and M18 and may be arranged between the first front side interconnection layer M11 and the eighth front side interconnection layer M18. The second front side interconnection layer M12 may be arranged between the third front side interconnection layer M13 and the first front side interconnection layer M11, the fifth front side interconnection layer M15 may be arranged between the third front side interconnection layer M13 and the eighth front side interconnection layer M18. The third front side interconnection layer M13, the fourth front side interconnection layer M14, and the fifth to seventh front side interconnection layers M15, M16, and M17 may each have a same width in the second horizontal direction (the Y direction) and may be spaced apart from each other in the first horizontal direction (the X direction). In some implementations, the third front side interconnection layer M13 and the fourth front side interconnection layer M14 may be formed by first creating a preliminary front side interconnection layer that extends in the first horizontal direction (the X direction) and then cutting the preliminary front side interconnection layer into two separate portions. Similarly, the fifth to seventh front side interconnection layers M15, M16, and M17 may also be formed by first creating a preliminary front side interconnection layer that extends in the first horizontal direction (the X direction) and then cutting the preliminary front side interconnection layer into three separate portions but are not limited thereto.

In some implementations, the back side interconnection layer BML may include a first back side interconnection layer M21, a second back side interconnection layer M22, a third back side interconnection layer M23, and a fourth back side interconnection layer M24. The first back side interconnection layer M21 may be spaced apart from the second back side interconnection layer M22 in the first horizontal direction (the X direction) and may be spaced apart from the third back side interconnection layer M23 in the second horizontal direction (the Y direction). The fourth back side interconnection layer M24 may be spaced apart from the second back side interconnection layer M22 in the second horizontal direction (the Y direction) and may be spaced apart from the third back side interconnection layer M23 in the first horizontal direction (the X direction). The first back side interconnection layer M21 and the second back side interconnection layer M22, and the third back side interconnection layer M23 and the fourth back side interconnection layer M24 may be spaced apart from each other in the first horizontal direction (the X direction), respectively. In some implementations, the first back side interconnection layer M21 and the second back side interconnection layer M22 may be formed by first creating a preliminary back side interconnection layer that extends in the first horizontal direction (the X direction) and then cutting the preliminary back side interconnection layer into two separate portions, and the third back side interconnection layer M23 and the fourth back side interconnection layer M24 may also be formed by first creating a preliminary back side interconnection layer that extends in the first horizontal direction (the X direction) and then cutting the preliminary back side interconnection layer into two separate portions, but are not limited thereto.

In some implementations, the first active region ACT1 and the second active region ACT2 may include a semiconductor material, such as Si, SiGe, Ge, SiGeSn, GaAs, InSb, GaP, GaSb, InAlAs, InGaAs, GaAsSb, or InP, etc. The first active region ACT1 and the second active region ACT2 may include regions that protrude in the vertical direction (the Z direction) from the front side of the substrate (not shown). The substrate may include a conductive region, such as a well doped with impurities, or a structure doped with impurities. In some implementations, the first active region ACT1 may include a p-channel metal oxide semiconductor (PMOS) region and the second active region ACT2 may include an n-channel metal oxide semiconductor (NMOS) region, but are not limited thereto.

In some implementations, a plurality of gate lines GL may extend in the second horizontal direction (the Y direction) and be spaced apart from each other in the first horizontal direction (the X direction). Each of the plurality of gate lines GL may include metal, metal nitride, metal carbide, or a combination thereof. The metal may be selected from a group including Ti, W, Ru, Nb, Mo, Hf, Ni, Co, Pt, Yb, Tb, Dy, Er, and Pd. The metal nitride may be selected from a group including TiN and TaN. The metal carbide may include TiAlC. However, materials constituting the gate line GL are not limited to those listed above.

In some implementations, a plurality of dummy gate lines DL may extend in the second horizontal direction (the Y direction) and be spaced apart from each other in the first horizontal direction (the X direction). Typically, the dummy gate lines DL may be formed at edges of the standard cell to separate the standard cell from adjacent standard cell. These dummy gate lines DL may be used for isolation only and may not perform any logic function. In certain semiconductor processes, these dummy gate lines DL may provide electrical isolation or dielectric isolation. In some implementations, some of the plurality of gate lines GL may be removed and an insulating structure may be formed at a location of each removed gate line GL to form a dummy gate line DL. A dummy gate line DL may be spaced apart from an adjacent gate line GL by 1 contacted poly pitch (CPP) in the first horizontal direction (the X direction). At this time, CPP may refer to a pitch between the gate lines GL spaced apart from each other in the first horizontal direction (the X direction).

Although the layout diagram of the standard cell 100 in FIG. 1 and the plan views in FIGS. 2A and 2B illustrate five gate lines GL and three dummy gate lines DL, this is merely an example, and the number and arrangement relationship of the gate lines GL and the dummy gate lines DL of the disclosure are not limited thereto.

The upper via VA1, the lower via VA2, the upper source/drain contact CA1, the lower source/drain contact CA2, the upper gate contact CB1, and the lower gate contact CB2 may include the same conductive material or different conductive materials. For example, the conductive material may include at least one material selected from a group including Co, Ni, W, Ti, Ta, Cu, Al, TiN, TaN, and combinations thereof, but is not limited thereto. In some implementations, a silicide layer may be formed on the source/drain regions (not shown) of the first and second active regions ACT1 and ACT2 prior to forming the conductive material. The silicide layer may include at least one material selected from a group including WSi, CoSi, NiSi, TiSi, MoSi, TaSi, and combinations thereof.

In some implementations, the upper via VA1, the upper source/drain contact CA1, and the upper gate contact CB1 may be arranged at a higher vertical level than the lower via VA2, the lower source/drain contact CA2, and the lower gate contact CB2, respectively. The upper via VA1, the lower via VA2, the upper source/drain contact CA1, the lower source/drain contact CA2, the upper gate contact CB1, and the lower gate contact CB2 may be between the back side interconnection layer BML and the front side interconnection layer FML. The upper via VA1, the upper source/drain contact CA1, and the upper gate contact CB1 may be electrically connected to the front side interconnection layer FML, and the lower via VA2, the lower source/drain contact CA2, and the lower gate contact CB2 may be electrically connected to the back side interconnection layer BML.

In the standard cell having the layout diagram of the implementations, the standard cell may correspond to, for example, a unit cell and thus may be used as a basic layout when designing an integrated circuit. To further elaborate on the standard cell, as semiconductor devices have become more highly integrated recently, much time and cost are being spent on layout design of integrated circuits, especially on device regions. Therefore, as one of technologies to save time and cost, a standard cell-based layout design technique may be used. The standard cell-based layout design technique may shorten the time required for layout design by pre-designing logic devices, such as OR gates or AND gates that are used repeatedly, as standard cells, storing the logic devices in a computer system, and then arranging and interconnecting the logic devices where needed, during layout design.

For example, the standard cell may include basic cells such as AND, OR, NOR, inverter, NAND, NOR, etc.; complex cells such as OAI (OR/AND/INVERTER) and AOI (AND/OR/INVERTER); or storage elements such as simple master-slave flip-flops and latches.

A standard cell design method involves preparing logic circuit blocks (i.e., cells) with various functions in advance and designing a dedicated large-scale integrated circuit (LSI) tailored to needs of a customer or user by arbitrarily combining the cells. Cells may be designed and verified in advance and then registered in a computer, and logic design, layout, and interconnection may be performed by combining the registered cells using computer aided design (CAD).

Specifically, in a case of designing/manufacturing a large-scale integrated circuit, after standardized logic circuit blocks (e.g., standard cells), are stored in a library at a certain scale, an entire circuit may be designed by selecting the standard cells that fit the current design purpose from the library, arranging the selected standard cells as multiple cells on a chip, and then performing optimal interconnection with the shortest interconnection length in an interconnection space between cells. The greater the number of types of cells stored in the library, the greater the design flexibility and the higher the potential for achieving optimal chip performance.

Referring again to the layout diagram of the standard cell 100 of the disclosure, both a plurality of the front side interconnection layers FML and a plurality of the back side interconnection layers BML may serve as power rails and signal rails and may be flexibly utilized depending on the user's settings, thereby improving the integration of devices.

In a cell including a plurality of power rails and a plurality of signal rails, some of the plurality of power rails may be applied with first power VDD, e.g., a power at a positive potential, and the remaining power rails may be applied with second power VSS, e.g., a power at a negative potential or a ground potential. Additionally, the plurality of signal rails may be arranged between the power rails in a plan view so that signals may be input to and output from a transistor through the plurality of signal rails. The power rails may be disposed at the top and bottom boundaries of the standard cell, and the signal rails may be disposed inside the standard cell and have a multilayer structure. However, in the related art, the interconnection layer area allocated for power rails is designed with a wide area, while only a portion of this area is actively utilized for power delivery, resulting in suboptimal space utilization efficiency. The standard cell of the disclosure may partially split the interconnection layer area allocated for power rails in the related art, so that some of the interconnection layers may be used as signal rails and some of the interconnection layers may be used as power rails. In addition, roles of signal rails and power rails may not be fixed but may be flexibly configured, so that the interconnection layer that acts as a signal rail may be used as a power rail, and the interconnection layer that acts as a power rail may be used as a signal rail.

For example, referring to FIG. 2A, when the eighth front side interconnection layer M18 is used as the power rail, a part of the interconnection layer that serves as a power rail in the related art, for example, the first front side interconnection layer M11, may be used as the signal rail, thereby supplementing insufficient power supply. That is, each interconnection layer may be used as the power rail or the signal rail depending on the cell design efficiency.

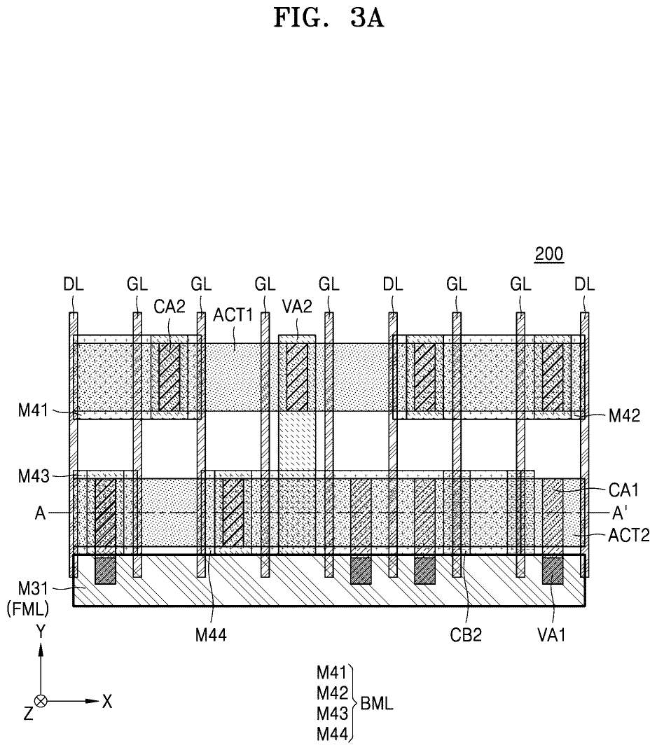

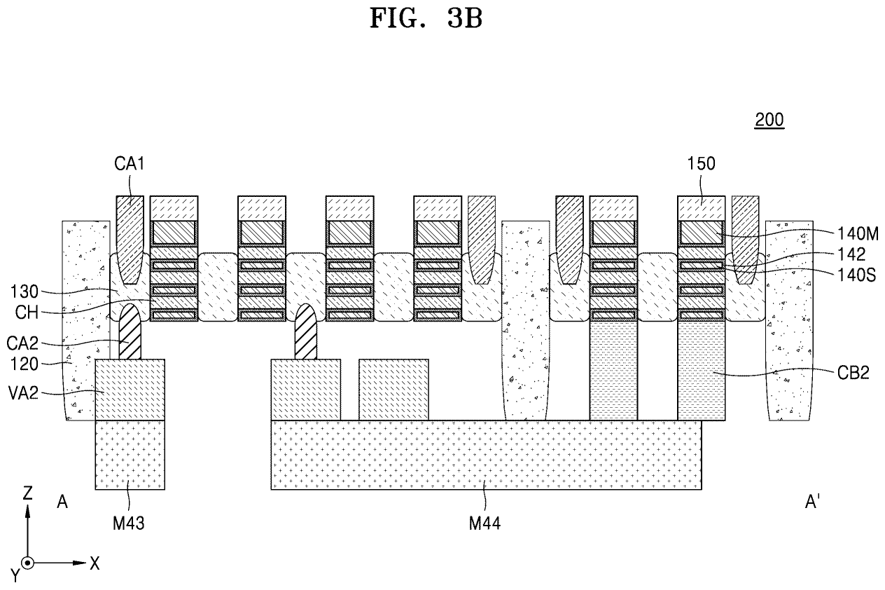

FIG. 3A is a layout diagram of a standard cell 200 according to some implementations, and FIG. 3B is a cross-sectional view taken along line A-A′ of FIG. 3A.

It will be understood that the standard cell 200 of FIGS. 3A and 3B is not mutually exclusive with the standard cell 100 described with reference to FIGS. 1, 2A, and 2B, and that components having the same reference numerals refer to the same components. In the following description, redundant explanations of identical components are omitted, with emphasis on differences from the standard cell 100 of FIGS. 1, 2A, and 2B.

Referring to FIGS. 3A and 3B, the standard cell 200 of the implementations may include the back side interconnection layer BML, the front side interconnection layer FML, the lower via VA2, the lower source/drain contact CA2, the lower gate contact CB2, the upper via VA1, the upper source/drain contact CA1, the first active region ACT1, the second active region ACT2, the gate line GL, and the dummy gate line DL.

In some implementations, the front side interconnection layer FML may include a first front side interconnection layer M31 that extends in the first horizontal direction (the X direction). Although FIG. 3A illustrates that there is one front side interconnection layer FML in the standard cell 200, this example is provided solely for purposes of simplicity and illustration and a plurality of the front side interconnection layers FML may be included.

In some implementations, the back side interconnection layer BML may include a first back side interconnection layer M41, a second back side interconnection layer M42, a third back side interconnection layer M43, and a fourth back side interconnection layer M44. The first back side interconnection layer M41 may be spaced apart from the second back side interconnection layer M42 in the first horizontal direction (the X direction) and may be spaced apart from the third back side interconnection layer M43 in the second horizontal direction (the Y direction). The fourth back side interconnection layer M44 may be spaced apart from the second back side interconnection layer M42 in the second horizontal direction (the Y direction) and may be spaced apart from the third back side interconnection layer M43 in the first horizontal direction (the X direction). The first back side interconnection layer M41 and the second back side interconnection layer M42, and the third back side interconnection layer M43 and the fourth back side interconnection layer M44 may be spaced apart from each other in the first horizontal direction (the X direction), respectively. In some implementations, the first back side interconnection layer M41 and the second back side interconnection layer M42 may be formed by first creating a preliminary back side interconnection layer that extends in the first horizontal direction (the X direction) and then cutting the preliminary back side interconnection layer into two separate portions, and the third back side interconnection layer M43 and the fourth back side interconnection layer M44 may also be formed by first creating a first preliminary back side interconnection layer that extends in the first horizontal direction (the X direction) and then cutting the preliminary back side interconnection layer into two separate portions, but are not limited thereto.

In some implementations, the plurality of gate lines GL may extend in the second horizontal direction (the Y direction) and be spaced apart from each other in the first horizontal direction (the X direction). In some implementations, the gate line GL may surround a channel layer CH with a gate all around (GAA) structure. The first active region ACT1 and the second active region ACT2 may each constitute a source/drain region 130 and the channel layer CH. In some implementations, each channel layer CH may have a multi-bridge channel (MBC) structure and may be surrounded on four sides by the gate line GL. Here, the four sides may include both sides in the first horizontal direction (the X direction) and both sides in the vertical direction (the Z direction). In some implementations, the channel layer CH may include at least two nanosheets.

The gate line GL may include a sub-gate 140S that covers an upper portion and a lower portion of the channel layer CH in the vertical direction (the Z direction), and a main gate 140M extending in the second horizontal direction (the Y direction) on an upper portion of a device isolation film (not shown). A thickness of the sub-gate 140S in the vertical direction (the Z direction) may be less than the thickness of the main gate 140M in the vertical direction (the Z direction).

A gate dielectric film 142 may be between the channel layer CH and the gate line GL. The gate dielectric film 142 may cover upper surfaces of the first active regions ACT1, the second active region ACT2, and the device isolation film, and surround the channel layer CH. The gate dielectric film 142 may include a laminated structure of a dielectric film and a high-k dielectric film. The high-k dielectric film may include a material with a higher dielectric constant than silicon dioxide. For example, the high-k dielectric film may have a dielectric constant of about 10 to about 25. The high-k dielectric film may include, but is not limited thereto, hafnium oxide.

The sub-gate 140S may be spaced apart from the source/drain region 130 in the first horizontal direction (the X direction) with the gate dielectric film 142 therebetween.

As illustrated in FIG. 3B, the source/drain region 130 may be formed on both sides of the channel layer CH in the first horizontal direction (the X direction). The source/drain region 130 may include an epitaxially grown semiconductor layer. In some implementations, the source/drain region 130 may include an epitaxially grown Si layer, an epitaxially grown SiC layer, or a plurality of epitaxially grown SiGe layers. When the source/drain region 130 constitutes an NMOS transistor, the source/drain region 130 may include a Si layer doped with an n-type dopant or a SiC layer doped with the n-type dopant. The n-type dopant may be selected from phosphorus (P), arsenic (As), and antimony (Sb). When the source/drain region 130 constitutes a PMOS transistor, the source/drain region 130 may include a SiGe layer doped with a p-type dopant. The p-type dopant may be selected from boron (B) and gallium (Ga).

In some implementations, the plurality of dummy gate lines DL may extend in the second horizontal direction (the Y direction) and be spaced apart from each other in the first horizontal direction (the X direction). In some implementations, a dummy gate line DL may be formed by removing a portion of a gate line GL and forming an insulating structure 120 at a location of the removed portion of the gate line GL. That is, each dummy gate line DL of FIG. 3A may correspond to an insulating structure 120 of FIG. 3B.

In some implementations, the insulating structure 120 may have a single diffusion break (SDB) structure. The SDB structure may include, for example, a structure in which an insulating layer having substantially the same width as the gate extends into the semiconductor substrate to separate the first active region ACT1 from the second active region ACT2. The insulating structure 120 may be formed in a space where one of the plurality of gate lines GL is removed, and may have a horizontal width substantially the same as the horizontal width of one gate line GL in the first horizontal direction (the X direction). In some implementations, a portion of an upper portion of the insulating structure 120 may protrude from the substrate.

As illustrated in FIG. 3B, an upper insulating film 150 may be formed to cover an upper surface of the main gate 140M of the gate line GL. The upper insulating film 150 may extend in the second horizontal direction (the Y direction).

Although the layout diagram of the standard cell 200 in FIGS. 3A and 3B illustrates that six gate lines GL and three dummy gate lines DL are included, this is merely an example, and the number and arrangement relationship of the gate lines GL and the dummy gate lines DL of the disclosure is not limited thereto.

In some implementations, the third back side interconnection layer M43 may be used as the power rail, and the fourth back side interconnection layer M44 may be used as the signal rail. Referring to the layout diagram of the standard cell 200 in FIG. 3B, when the third back side interconnection layer M43 is used as the power rail and when power is transmitted from the back side of the substrate to the front side of the substrate, the power may reach the front side of the substrate from the third back side interconnection layer M43, through the lower via VA2 contacting the third back side interconnection layer M43, the lower source/drain contact CA2 contacting the lower via VA2, the source/drain region 130 contacting the lower source/drain contact CA2, and the upper source/drain contact CA1 contacting the source/drain region 130. In addition, the power transmitted through the lower source/drain contact CA2 may be further transmitted in the first horizontal direction (the X direction) through the source/drain region 130 and the channel layer CH. In addition, referring to FIG. 3A, the upper source/drain contact CA1, which is positioned at a position overlapping the third back side interconnection layer M43, may extend in the second horizontal direction (the Y direction), so the third back side interconnection layer M43 may be electrically connected to the first front side interconnection layer M31 through a path described above. Alternatively, the flow direction of current may be changed depending on the user's settings, so the power may be transmitted in the opposite direction to that described above.

Next, unlike the third back side interconnection layer M43 used as the power rail, when the fourth back side interconnection layer M44 is used as the signal rail, signals may be transmitted from the back side of the substrate through the lower gate contact CB2, etc., without using the front side interconnection layer FML, so that electrical characteristics may be improved by shortening a signal travel path even with a relatively small number of interconnection layers. A signal that is transmitted from the fourth back side interconnection layer M44 through the lower gate contact CB2 may be additionally transmitted in the first horizontal direction (the X direction) through the source/drain region 130 adjacent to the channel layer CH that is arranged at a position vertically overlapping the lower gate contact CB2. In addition, the fourth back side interconnection layer M44 may contact both the lower gate contact CB2 and some of the lower vias VA2, so that the lower vias VA2 that contact the fourth back side interconnection layer M44 may be electrically connected to the lower gate contact CB2 through the fourth back side interconnection layer M44.

However, as described above, the front side interconnection layer FML and the back side interconnection layer BML may be used as either the signal rail or the power rail, and therefore, are not limited to the layout diagram of standard cell 200 of the implementations. That is, the third back side interconnection layer M43 may be used as the signal rail in other implementations, and the fourth back side interconnection layer M44 may also be used as the power rail in other implementations.

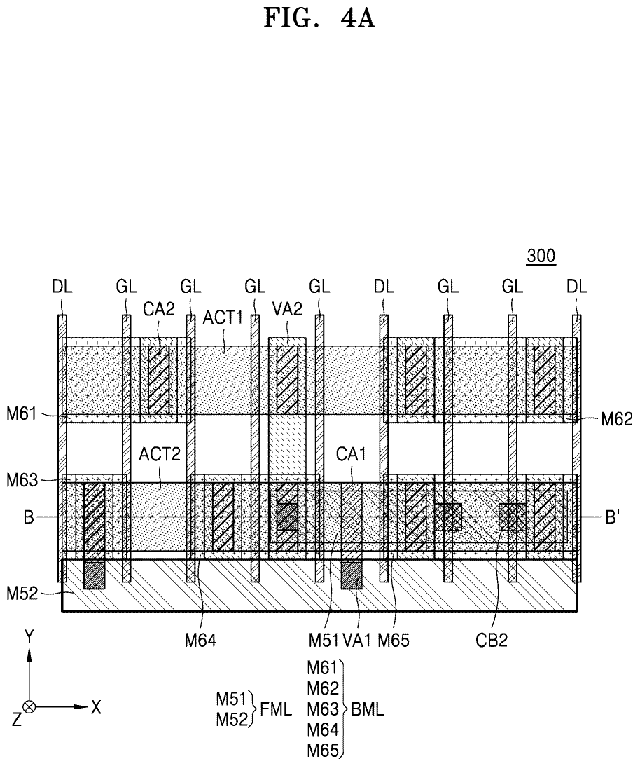

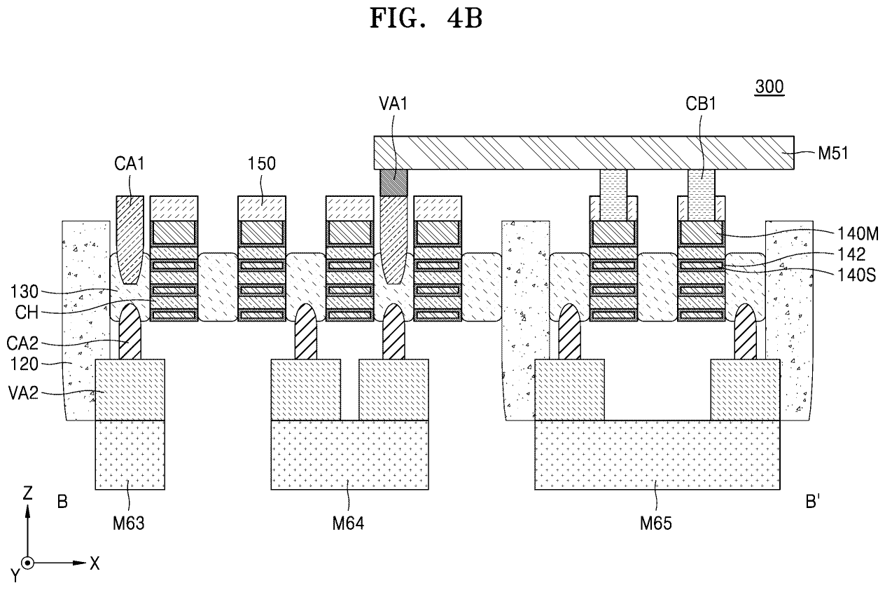

FIG. 4A is a layout diagram of a standard cell 300 according to some implementations, and FIG. 4B is a cross-sectional view taken along line B-B′ of FIG. 4A.

It will be understood that the standard cell 300 of FIGS. 4A and 4B is not mutually exclusive with the standard cell 100 described with reference to FIGS. 1, 2A, and 2B, and the standard cell 200 described with reference to FIGS. 3A and 3B, and that components having the same reference numerals refer to the same components. In the following description, redundant explanations of identical components are omitted, with emphasis on differences from the standard cell 100 of FIGS. 1, 2A, and 2B and the standard cell 200 of FIGS. 3A and 3B.

Referring to FIGS. 4A and 4B, the standard cell 300 of the implementations may include the back side interconnection layer BML, the front side interconnection layer FML, the lower via VA2, the lower source/drain contact CA2, the upper via VA1, the upper source/drain contact CA1, the first active region ACT1, the second active region ACT2, the gate line GL, the dummy gate line DL, and the upper gate contact CB1.

In some implementations, the front side interconnection layer FML may include a first front side interconnection layer M51 and a second front side interconnection layer M52 that are spaced apart from each other in the second horizontal direction (the Y direction) and each of the first front side interconnection layer M51 and the second front side interconnection layer M52 extends in the first horizontal direction (the X direction). Sizes and positions of the first front side interconnection layer M51 and the second front side interconnection layer M52, and a structure of the front side interconnection layer FML of the disclosure are not limited to implementations illustrated in FIGS. 4A and 4B.

In some implementations, the back side interconnection layer BML may include a first back side interconnection layer M61, a second back side interconnection layer M62, a third back side interconnection layer M63, a fourth back side interconnection layer M64, and a fifth back side interconnection layer M65.

The first back side interconnection layer M61 may be spaced apart from the second back side interconnection layer M62 in the first horizontal direction (the X direction) and may be spaced apart from the third back side interconnection layer M63 in the second horizontal direction (the Y direction). The fifth back side interconnection layer M65 may be spaced apart from the third back side interconnection layer M63 in the first horizontal direction (the X direction), and the fourth back side interconnection layer M64 may be arranged between the third back side interconnection layer M63 and the fifth back side interconnection layer M65. The second back side interconnection layer M62 may be spaced apart from the fifth back side interconnection layer M65 in the second horizontal direction (the Y direction). In some implementations, the first back side interconnection layer M61 and the second back side interconnection layer M62 may be formed by first creating a preliminary back side interconnection layer that extends in the first horizontal direction (the X direction) and then cutting the preliminary back side interconnection layer into two separate portions. Similarly, the third back side interconnection layer M63, the fourth back side interconnection layer M64, and the fifth back side interconnection layer M65 may also be formed by first creating a preliminary back side interconnection layer that extends in the first horizontal direction (the X direction) and then cutting the preliminary back side interconnection layer into three separate portions, but are not limited thereto.

Descriptions of the gate line GL, the dummy gate line DL, the insulating structure 120, the source/drain region 130, the channel layer CH, the main gate 140M, the sub-gate 140S, the gate dielectric film 142, and the upper insulating film 150 of FIGS. 4A and 4B may be the same as those described above with reference to the standard cell 200 of FIGS. 3A and 3B, and therefore, descriptions of components mentioned above may be omitted.

Although the layout diagram of the standard cell 300 in FIGS. 4A and 4B illustrates six gate lines GL and three dummy gate lines DL, this is merely an example, and the number and arrangement relationship of the gate lines GL and the dummy gate lines DL of the disclosure are not limited thereto.

In some implementations, the third back side interconnection layer M63 and the fifth back side interconnection layer M65 may be used as power rails, and the fourth back side interconnection layer M64 may be used as the signal rail. Referring to the layout diagram of the standard cell 300 in FIG. 4B, when the third back side interconnection layer M63 is used as the power rail and when power is transmitted from the back side of the substrate to the front side of the substrate, the power may reach the front side of the substrate from the third back side interconnection layer M63, through the lower via VA2 contacting the third back side interconnection layer M63, the lower source/drain contact CA2 contacting the lower via VA2, the source/drain region 130 contacting the lower source/drain contact CA2, and the upper source/drain contact CA1 contacting the source/drain region 130. In addition, referring to FIG. 4A, the upper source/drain contact CA1, which is arranged at a position overlapping the third back side interconnection layer M63, may extend in the second horizontal direction (the Y direction), so that the third back side interconnection layer M63 may be electrically connected to the second front side interconnection layer M52 through a path described above. Alternatively, the flow direction of current may be changed depending on the user's settings, so that the power may be transmitted in the opposite direction to that described above. In addition, the power transmitted through the lower source/drain contact CA2 may be further transmitted in the first horizontal direction (the X direction) through the source/drain region 130 and the channel layer CH.

Next, the fifth back side interconnection layer M65 may also be used as the power rail, and the lower source/drain contacts CA2 disposed at a position vertically overlapping the fifth back side interconnection layer M65 may be electrically connected to the fifth back side interconnection layer M65. That is, power may be transmitted to and received from the bottom of the substrate without using the front side interconnection layer FML, so that according to the disclosure, the power may be transmitted efficiently using fewer interconnection layers that are flexibly assigned as signal rails and power rails. In addition, although the illustration is omitted in FIG. 4B, electrical connection between the third back side interconnection layer M63 and the fifth back side interconnection layer M65 may be also possible through additional interconnection layers arranged below the third back side interconnection layer M63 and the fifth back side interconnection layer M65. In addition, in some implementations, the fifth back side interconnection layer M65 may be electrically connected to the first front side interconnection layer M51 through the lower via VA2 contacting the fifth back side interconnection layer M65, the lower source/drain contact CA2 contacting the lower via VA2, the source/drain region 130 contacting the lower source/drain contact CA2, the channel layer CH connected to the source/drain region 130, and the upper gate contact CB1 connected to the channel layer CH.

Next, unlike the third back side interconnection layer M63 and the fifth back side interconnection layer M65 which are used as power rails, when the fourth back side interconnection layer M64 is used as the signal rail, the fourth back side interconnection layer M64 may be electrically connected to the first front side interconnection layer M51 through the lower via VA2 arranged at a position vertically overlapping the fourth back side interconnection layer M64, the lower source/drain contact CA2 contacting the lower via VA2, the source/drain region 130 contacting the lower source/drain contact CA2, the upper source/drain contact CA1 contacting the source/drain region 130, and the upper via VA1 contacting the source/drain contact CA1, to transmit or receive signals.

However, as described above, the front side interconnection layer FML and the back side interconnection layer BML may be used as either the signal rail or the power rail, and therefore, are not limited to the layout diagram of standard cell 300 of the implementations. That is, the third back side interconnection layer M63 and/or the fifth back side interconnection layer M65 may be used as signal rails in other implementations, and the fourth back side interconnection layer M64 may also be used as the power rail in other implementations.

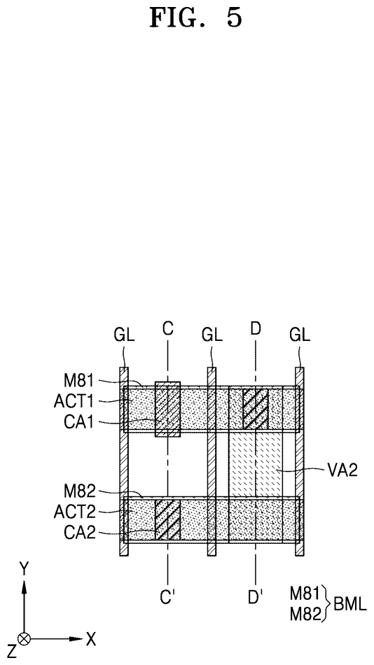

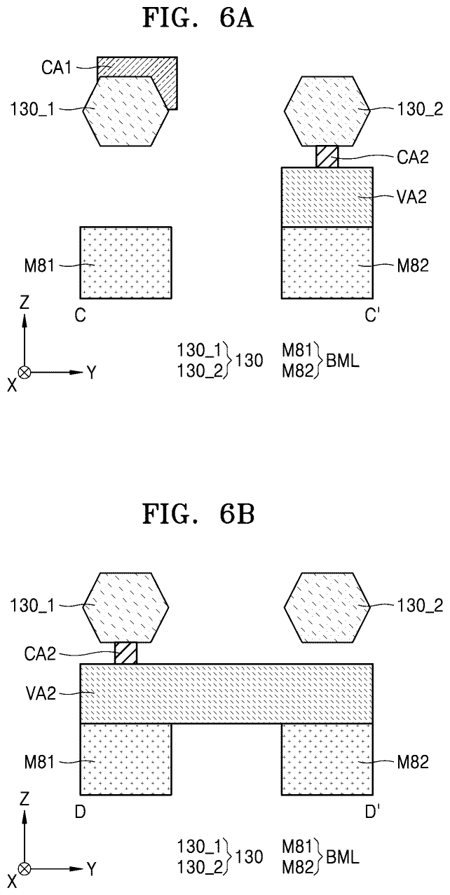

FIG. 5 is a plan view schematically illustrating a portion of a layout diagram to explain the connection between the PMOS region and the NMOS region in a standard cell according to some implementations. FIG. 6A is a cross-sectional view taken along line C-C′ of FIG. 5, and FIG. 6B is a cross-sectional view taken along line D-D′ of FIG. 5.

The first active region ACT1, the second active region ACT2, the source/drain region 130, and the gate line GL of FIG. 5 may be the same as those described above, and thus, descriptions of components mentioned above may be simplified or omitted below.

Referring to FIGS. 5, 6A, and 6B together, the back side interconnection layer BML may include a first back side interconnection layer M81 and a second back side interconnection layer M82. The first back side interconnection layer M81 and the second back side interconnection layer M82 may each extend in the first horizontal direction (the X direction) and be spaced apart from each other in the second horizontal direction (the Y direction).

Referring to FIGS. 6A and 6B, the source/drain region 130 may include a first source/drain region 130_1 and a second source/drain region 130_2. The first source/drain region 130_1 may constitute, for example, a portion of the PMOS region, and the second source/drain region 130_2 may constitute, for example, a portion of the NMOS region. That is, the first source/drain region 130_1 may be doped with the p-type dopant, and the second source/drain region 130_2 may be doped with the n-type dopant. In FIGS. 6A and 6B, the first source/drain region 130_1 and the second source/drain region 130_2 are illustrated as each having a hexagonal cross-section, but this is merely example, and the first source/drain region 130_1 and the second source/drain region 130_2 may have polygonal cross-sections of other shapes.

Referring to FIG. 6B, the first source/drain region 130_1 may be connected to the lower via VA2 through the lower source/drain contact CA2, and may also be electrically connected to the first back side interconnection layer M81 and the second back side interconnection layer M82 through the lower via VA2. Next, referring to FIG. 6A, the second back side interconnection layer M82 may be connected to the lower via VA2 and the lower source/drain contact CA2, and thus may be electrically connected to the second source/drain region 130_2. That is, signals may be transmitted from PMOS to NMOS using the back side interconnection layer BML without the front side interconnection layer FML, which may provide flexibility in design of the layout of the standard cell, and may lead to interconnection simplification and increased device integration.

As described above, some implementations have been disclosed in the drawings and specification. Although specific terms have been used in the specification to describe implementations, the terms are used only for the purpose of explaining the disclosure and are not intended to limit the meaning or the scope of the disclosure set forth in the claims. Therefore, one of ordinary skill in the art will understand that various modifications and equivalent other implementations are possible from the disclosure.

As used herein, the term “at least one of” can refer to and encompass any and all possible combinations of one or more of the associated listed terms. For example, the term “at least one of A, B, or C” means that (i) at least one of A, (ii) at least one of B, (iii) at least one of C, (iv) at least one of A and at least one of B, (v) at least one of B and at least one of C, (vi) at least one of A and at least one of C, or (vi) at least one of A, at least one of B and at least one of C are possible, where A, B and C may be singular or plural.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the disclosurehas been particularly shown and described with reference to implementationsthereof, it will be understood that various changes in form and details may be made therein without departing from the spirit and scope of the following claims.

What is claimed is:

1. A standard cell comprising:
a plurality of back side interconnection layers extending in a first horizontal direction;
a lower via disposed on the plurality of back side interconnection layers;
a first transistor disposed at a higher vertical level than the lower via, wherein the first transistor comprises a gate line extending in a second horizontal direction perpendicular to the first horizontal direction, source/drain regions arranged on sides of the gate line in the first horizontal direction, and a channel layer between the source/drain regions and surrounded by the gate line;
a lower source/drain contact between the lower via and the source/drain regions;
an upper source/drain contact formed on the source/drain regions;
a plurality of front side interconnection layers extending in the first horizontal direction; and
an upper via between the upper source/drain contact and the plurality of front side interconnection layers,
wherein the plurality of back side interconnection layers comprise at least one first back side interconnection layer and at least one second back side interconnection layer spaced apart from the first back side interconnection layer in the first horizontal direction, and
wherein the plurality of front side interconnection layers comprise at least one first front side interconnection layer and at least one second front side interconnection layer spaced apart from the first back side interconnection layer in the first horizontal direction.

2. The standard cell of claim 1, wherein the first back side interconnection layer comprises a power rail and the second back side interconnection layer comprises a signal rail.

3. The standard cell of claim 2, wherein the first back side interconnection layer and the second back side interconnection layer have a same width in the second horizontal direction.

4. The standard cell of claim 2, comprising a lower gate contact between the second back side interconnection layer and the gate line.

5. The standard cell of claim 1, wherein the first front side interconnection layer comprises a power rail and the second front side interconnection layer comprises a signal rail.

6. The standard cell of claim 5, wherein the first front side interconnection layer and the second front side interconnection layer have a same width in the second horizontal direction.

7. The standard cell of claim 5, wherein a first power is configured to be applied to the second front side interconnection layer.

8. The standard cell of claim 1, wherein the source/drain regions comprise a p-channel metal oxide semiconductor (PMOS) region and an n-channel metal oxide semiconductor (NMOS) region, and
wherein the PMOS region is electrically connected to the NMOS region through at least one of the plurality of back side interconnection layers.

9. The standard cell of claim 1, wherein at least one of the first back side interconnection layer, the second back side interconnection layer, the first front side interconnection layer, or the second front side interconnection layer comprises a power rail.

10. The standard cell of claim 1, wherein at least one of the first back side interconnection layer, the second back side interconnection layer, the first front side interconnection layer, or the second front side interconnection layer comprises a signal rail.

11. The standard cell of claim 1, wherein the lower via extends in the second horizontal direction.

12. The standard cell of claim 1, comprising an upper gate contact disposed on the gate line.

13. A standard cell comprising:
a back side interconnection layer comprising at least one back side power rail and at least one back side signal rail that extend in a first horizontal direction, respectively;
a lower via disposed on the back side interconnection layer;
a channel layer disposed at a higher vertical level than the lower via;
a gate line that surrounds the channel layer and extends in a second horizontal direction intersecting the first horizontal direction;
source/drain regions arranged on both sides of the channel layer in the first horizontal direction;
a lower source/drain contact between the source/drain regions and the lower via;
an upper source/drain contact disposed on the source/drain regions;
a front side interconnection layer comprising at least one front side power rail and at least one front side signal rail that extend in the first horizontal direction at a higher vertical level than the source/drain regions; and
an upper via between the front side interconnection layer and the upper source/drain contact.

14. The standard cell of claim 13, wherein the at least one back side power rail and the at least one back side signal rail are spaced apart from each other in the first horizontal direction.

15. The standard cell of claim 14, wherein a width of the at least one back side power rail in the second horizontal direction is a same as a width of the at least one back side signal rail in the second horizontal direction.

16. The standard cell of claim 13, wherein the at least one front side power rail and the at least one front side signal rail are spaced apart from each other in first horizontal direction.

17. The standard cell of claim 16, wherein a width of the at least one front side power rail in the second horizontal direction is a same as a width of the at least one front side signal rail in the second horizontal direction.

18. The standard cell of claim 13, comprising a lower gate contact disposed at a position vertically overlapping the gate line, wherein the lower gate contact is disposed on the at least one back side signal rail.

19. The standard cell of claim 13, comprising an upper gate contact which is disposed at a position vertically overlapping the gate line and is connected to the front side interconnection layer.

20. A standard cell comprising:
a plurality of back side interconnection layers spaced apart from each other in a first horizontal direction and a second horizontal direction intersecting the first horizontal direction, wherein the plurality of back side interconnection layers are arranged at a first vertical level;
a plurality of gate lines spaced apart from each other in the first horizontal direction and each extending in the second horizontal direction, wherein the plurality of gate lines are arranged at a second vertical level higher than the first vertical level;
a channel layer surrounded by the plurality of gate lines;
source/drain regions disposed on both sides of the channel layer; and
a plurality of front side interconnection layers spaced apart from each other in the first horizontal direction and the second horizontal direction, wherein the plurality of front side interconnection layers are arranged at a third vertical level higher than the second vertical level,
wherein the plurality of back side interconnection layers and the plurality of front side interconnection layers comprise at least one signal rail and at least one power rail.
